(19) United States
(12) Patent Application Publication
(10) Pub. No.: US 2017/0012576 A1
(43) Pub. Date: Jan. 12, 2017

(54) INTERCONNECTOR AND SOLAR PANEL

(71) Applicants: KABUSHIKI KAISHA TOYOTA JIDOSHOKKI, Kariya-shi (JP); TOYOTA JIDOSHA KABUSHIKI KAISHA, Toyota-shi (JP)

(72) Inventors: Hirotaka INABA, Kariya-shi (JP); Kazutaka KIMURA, Susono-shi (JP)

(73) Assignees: KABUSHIKI KAISHA TOYOTA JIDOSHOKKI, Kariya-shi (JP); TOYOTA JIDOSHA KABUSHIKI KAISHA, Toyota-shi (JP)

(21) Appl. No.: 15/200,198

(22) Filed: Jul. 1, 2016

(30) Foreign Application Priority Data
Jul. 6, 2015 (JP) 2015-134973

(51) Int. Cl. H02S 40/34; H01L 31/048; H01L 31/049; H02S 40/38

(52) U.S. Cl. CPC H02S 40/34; H02S 40/38; H01L 31/0488; H01L 31/049

(57) ABSTRACT

An interconnector includes a first electrode configured to be connected to a first photovoltaic battery cell, a second electrode configured to be connected to a second photovoltaic battery cell, and a connection body that connects the first electrode and the second electrode. The connection body includes a first detour portion, a second detour portion, and a first connection portion. The first detour is electrically connected to the first electrode and extended toward a first side in a second direction orthogonal to a first direction. The second detour is electrically connected to the second electrode and extended toward the first side in the second direction. The first connection portion extends toward the first detour portion and the second detour portion in the first direction and connects the first detour portion and the second detour portion.

### BACKGROUND OF THE INVENTION

The present invention relates to an interconnector and a solar panel.

Japanese Laid-Open Patent Publication No. 2005-191479 discloses a conventional solar panel including a protection cover, a back cover, a first photovoltaic battery cell, a second photovoltaic battery cell, an interconnector, and an encapsulant.

The protection cover is formed from inorganic glass and is translucent from the front surface to the rear surface. The back cover is formed by a resin film or the like. The first photovoltaic battery cell and the second photovoltaic battery cell are adjacent to each other in a first direction.

The interconnector is flat. The interconnector is arranged to be horizontal to the first photovoltaic battery cell and the second photovoltaic battery cell between the first photovoltaic battery cell and the second photovoltaic battery cell. The interconnector includes a first electrode connected to the first photovoltaic battery cell, a second electrode connected to the second photovoltaic battery cell, and a connection portion that connects the first electrode and the second electrode to each other. The encapsulant is located between the protection cover and the back cover to fix the first photovoltaic battery cell, the second photovoltaic battery cell, and the interconnector in an encapsulated state.

In the solar panel, the interconnector electrically connects the first photovoltaic battery cell and the second photovoltaic battery cell, which are adjacent to each other in the first direction.

Temperature changes expand and contract such a solar panel during manufacturing and use. This changes the interval between the adjacent first and second photovoltaic battery cells. Thus, in the conventional solar panel, when a temperature change causes contraction, the interval narrows between the first and second photovoltaic battery cells. Accordingly, the first and second photovoltaic battery cells press opposite sides of the interconnector and apply load to the interconnector. The load may break the interconnector in the thickness-wise direction. When a temperature change widens the interval between the first and second photovoltaic battery cells, the first and second photovoltaic battery cells pull the opposite sides of the interconnector and apply load to the interconnector. The load may separate the first electrode from the first photovoltaic battery cell or separate the second electrode from the second photovoltaic battery cell.

As a result, electrical connection between the first photovoltaic battery cell and the second photovoltaic battery cell may be impeded in the solar panel. In particular, when the protection cover and the back cover are formed from a resin, the above problem becomes more prominent.

### SUMMARY OF THE INVENTION

It is an object of the present invention to provide an interconnector and a solar panel that reduce the occurrence of defective electrical connections between the first photovoltaic battery cell and the second photovoltaic battery cell even when the temperature changes cause expansion and contraction.

A first aspect of the present invention is an interconnector that is configured to electrically connect a first photovoltaic battery cell and a second photovoltaic battery cell. The first photovoltaic battery cell and the second photovoltaic battery cell are adjacent to each other in a first direction. The interconnector includes a first electrode configured to be connected to the first photovoltaic battery cell, a second electrode configured to be connected to the second photovoltaic battery cell, and a connection body that connects the first electrode and the second electrode. A second direction is defined orthogonal to the first direction, and a first side and a second side are defined in the second direction. The connection body includes a single first detour portion that is electrically connected to the first electrode and extended toward the first side in the second direction, a single second detour portion that is electrically connected to the second electrode and extended toward the first side in the second direction, and a single first connection portion that extends toward the first detour portion and the second detour portion in the first direction and connects the first detour portion and the second detour portion.

A second aspect of the present invention is an interconnector that is configured to electrically connect a first photovoltaic battery cell and a second photovoltaic battery cell. The first photovoltaic battery cell and the second photovoltaic battery cell are adjacent to each other in a first direction. The interconnector includes a first electrode configured to be connected to the first photovoltaic battery cell, a second electrode configured to be connected to the second photovoltaic battery cell, and a connection body that connects the first electrode and the second electrode. A second direction is defined orthogonal to the first direction, and a first side and a second side are defined in the second direction. The connection body includes a single first detour portion that is electrically connected to the first electrode and extended toward the first side in the second direction, a single second detour portion that is electrically connected to the second electrode and extended toward the first side in the second direction, a single first connection portion that extends toward the first detour portion and the second detour portion in the first direction and connects the first detour portion and the second detour portion, a single third detour portion that is electrically connected to the first electrode and extended toward the second side in the second direction, a single fourth detour portion that is electrically connected to the second electrode and extended at the second side in the second direction, and a single second connection portion that extends toward the third detour portion and the fourth detour portion in the first direction and connects the third detour portion and the fourth detour portion.

A third aspect of the present invention is a solar panel. The solar panel includes an interconnector, a protection cover that is translucent from a front surface to a rear surface, a back cover, a first photovoltaic battery cell, a second photovoltaic battery cell that is adjacent to the first photovoltaic battery cell in a first direction, and an encapsulant that encapsulates and fixes the first photovoltaic battery cell, the second photovoltaic battery cell, and the interconnector between the protection cover and the back cover. A second direction is defined orthogonal to the first direction, and a first side and a second side are defined in the second direction. The interconnector includes a first electrode connected to the first photovoltaic battery cell, a second electrode connected to the second photovoltaic battery cell, and a connection body that connects the first electrode and the second electrode. The connection body includes a single first detour portion that is electrically connected to the first electrode and extended toward the first side in the second direction, a single second detour portion that is electrically connected to the second electrode and extended toward the first side in the second direction, and a single first connection portion that extends toward the first detour portion and the second detour portion in the first direction and connects the first detour portion and the second detour portion.

Other aspects and advantages of the present invention will become apparent from the following description, taken in conjunction with the accompanying drawings, illustrating by way of example the principles of the invention.

### BRIEF DESCRIPTION OF THE DRAWINGS

The invention, together with objects and advantages thereof, may best be understood by reference to the following description of the presently preferred embodiments together with the accompanying drawings in which:

FIG. 1 is a top view showing a first embodiment of a solar panel;

FIG. 2 is an enlarged cross-sectional view taken along line A-A in FIG. 1;

FIG. 3 is an enlarged top view of a first photovoltaic battery cell, a second photovoltaic battery cells, and an interconnector of the solar panel shown in FIG. 1;

FIG. 4 is an enlarged top view of the interconnector of the solar panel shown in FIG. 1;

FIG. 5 is a cross-sectional view showing a preparation step of a manufacturing process in the solar panel shown in FIG. 1;

FIG. 6 is a cross-sectional view showing an encapsulation step of the manufacturing process in the solar panel shown in FIG. 1;

FIG. 7 is a cross-sectional view showing a lamination step of the manufacturing process in the solar panel shown in FIG. 1;

FIG. 8 is an enlarged top view showing region X in FIG. 3 when the solar panel of the first embodiment contracts;

FIG. 9 is an enlarged top view showing region X in FIG. 3 when the solar panel of the first embodiment expands;

FIG. 10 is an enlarged top view showing an interconnector in a second embodiment of the solar panel;

FIG. 11 is an enlarged top view showing an interconnector in a third embodiment of the solar panel; and

FIG. 12 is an enlarged cross-sectional view of an interconnector of a solar panel in a third embodiment taken along line B-B in FIG. 11.

### DETAILED DESCRIPTION OF THE PREFERRED EMBODIMENTS

First to third embodiments will now be described with reference to the drawings.

### First Embodiment

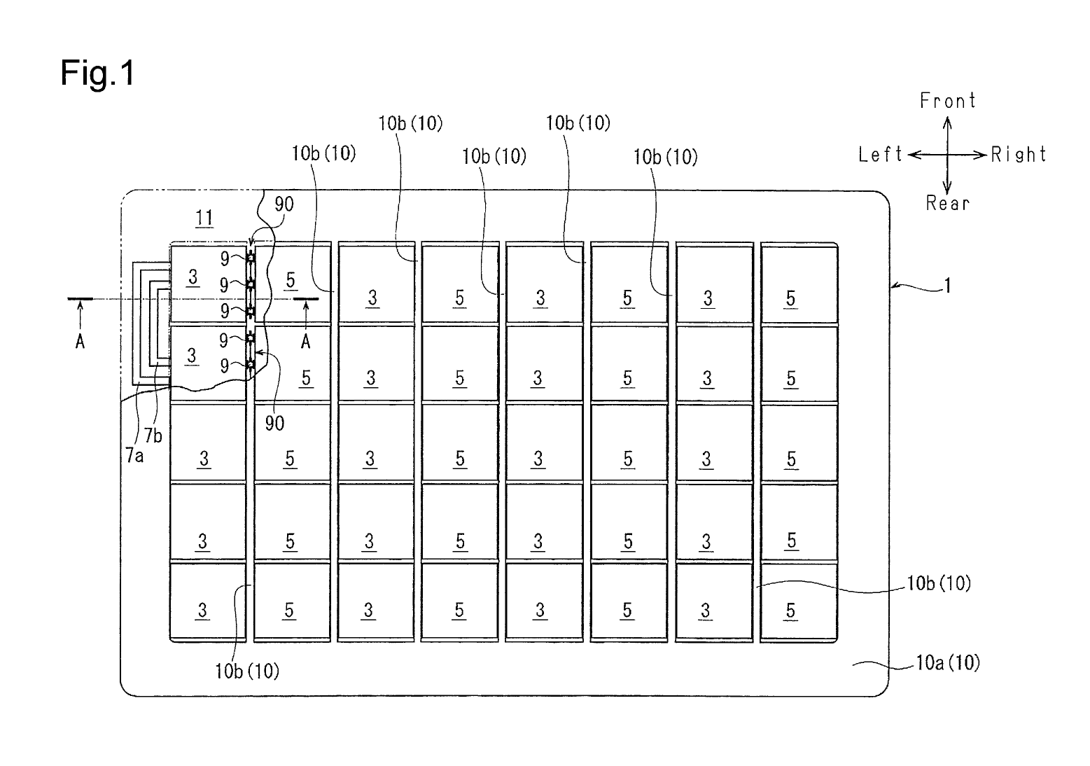

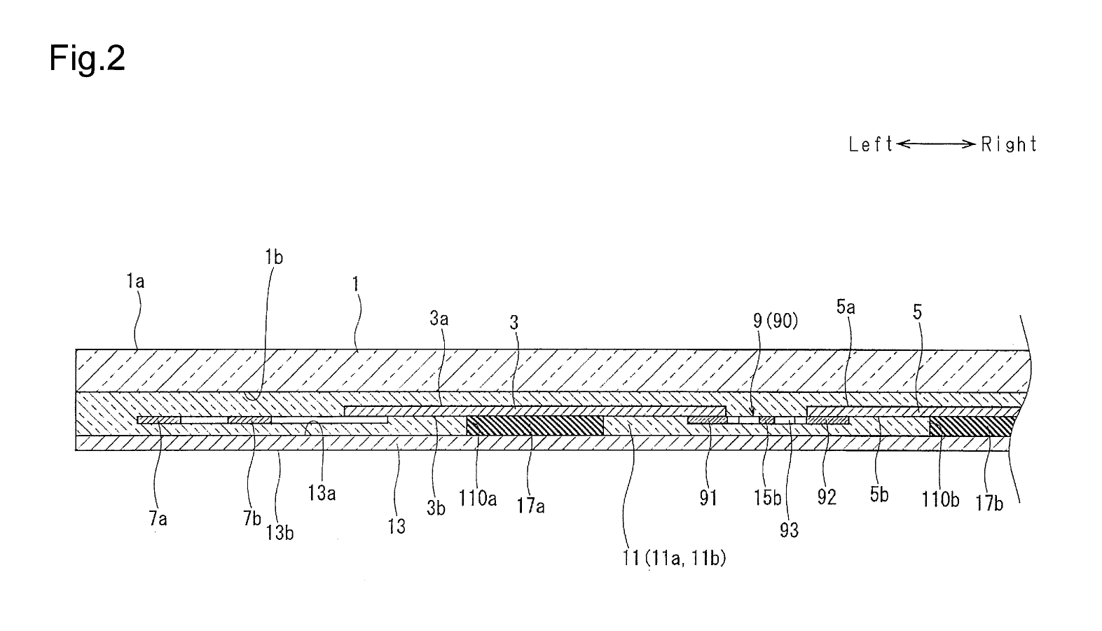

As shown in FIG. 1, a solar panel of the first embodiment includes a protection plate 1, first photovoltaic battery cells 3, second photovoltaic battery cells 5, tab wires 7a and 7b, interconnectors 9, an encapsulant 11, and a back panel 13, which is shown in FIG. 2. The protection plate 1 corresponds to a protection cover, and the back panel 13 corresponds to a back cover. To facilitate understanding, the protection plate 1 is not shown in the portion illustrated by broken lines in FIG. 1.

In the present embodiment, the arrows in FIG. 1 indicate the left, right, front, and rear directions of the solar panel. The direction extending from the left to the right is orthogonal to the direction extending from the front to the rear. The directions in the other drawings such as FIG. 2 correspond to the directions shown in FIG. 1, and the thickness-wise direction of the solar panel defines the vertical direction. The left-to-right (lateral) direction of the solar panel corresponds to a first direction. More specifically, the left side corresponds to a first side of the first direction, and the right side corresponds to a second side of the first direction. The front-to-rear direction of the solar panel corresponds to a second direction. More specifically, the rear side corresponds to a first side of the second direction, and the front side corresponds to a second side of the second direction. The directions of the solar panel are merely examples and irrelevant to the directions during use of the solar panel.

Referring to FIG. 2, the protection plate 1 is formed from a resin, the main component of which is polycarbonate. The protection plate 1 is translucent from a front surface la to a rear surface 1b. The front surface 1a of the protection plate 1 serves as a front surface of the solar panel, that is, a design surface of the solar panel. The front surface 1a is flat and horizontal, and the rear surface 1b is flat and parallel to the front surface 1a. Thus, the protection plate 1 is rectangular as shown in FIG. 1. The protection plate 1 may be formed from other resins, inorganic glass, or the like. The protection plate 1 may be designed to have a suitable thickness. A protection cover may be formed by, for example, a member such as a translucent protection film instead of the protection plate 1.

The protection plate 1 includes a shield 10. The shield 10 includes a main body 10a and connection portions 10b. The main body 10a conceals the tab wires 7a and 7b from the front surface 1a of the protection plate 1. The connection portions 10b conceal the interconnectors 9, a first connection portion 15a (described below), and a second connection portion 15b (described below) from the front surface 1a.

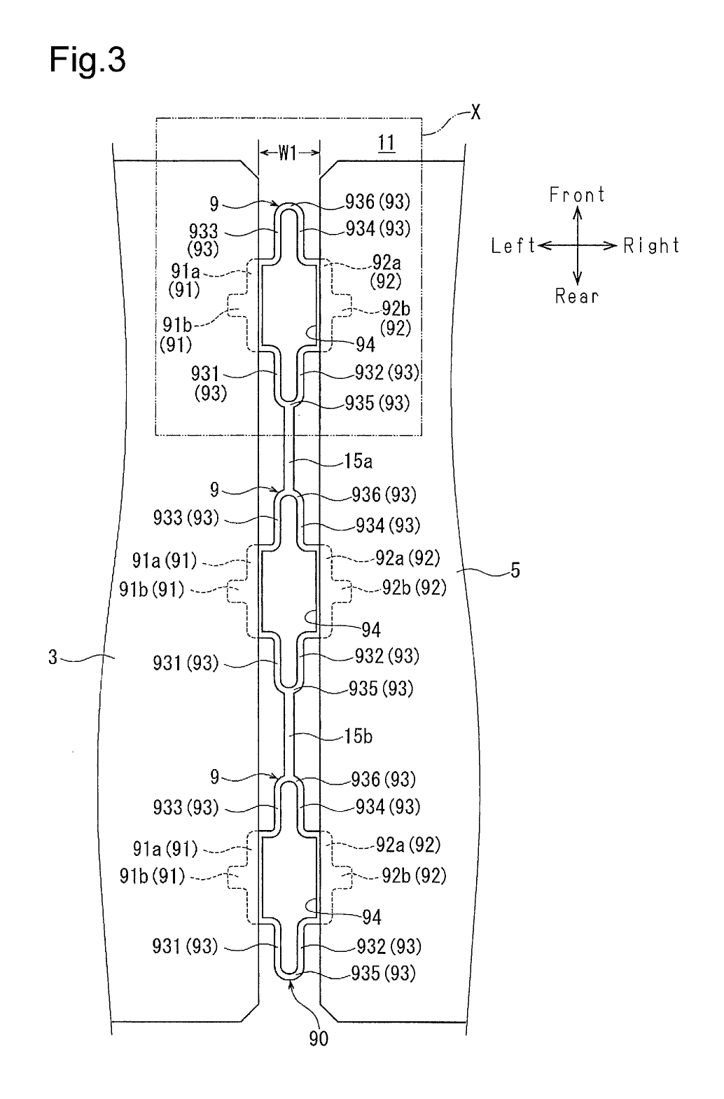

The main body 10a and the connection portions 10b are formed by painting or printing an opaque color such as black to predetermined portions on the rear surface 1b of the protection plate 1. More specifically, the main body 10a is located in the region of the plate 1 outside the first photovoltaic battery cells 3 and the second photovoltaic battery cells 5 and has the form of a frame that surrounds the first photovoltaic battery cells 3 and the second photovoltaic battery cells 5. The connection portions 10b are located at the inner side of the main body 10a and extended in the front-to-rear direction of the protection plate 1 to be continuous with a front side and a rear side of the main body 10a. The number of the connection portions 10b corresponds to the number of intervals between the first photovoltaic battery cells 3 and the second photovoltaic battery cells 5 that are adjacent in the lateral direction. Further, the size of each connection portion 10b corresponds to the size of each interval between the first photovoltaic battery cells 3 and the second photovoltaic battery cells 5 that are adjacent in the lateral direction. More specifically, the size of each connection portion 10b corresponds to the size of the interval W1 (refer to FIG. 3), which will be described below. To facilitate understanding, the shield 10 is not shown in FIGS. 2 and 5 to 7.

Referring to FIG. 2, crystal silicon is used in the first photovoltaic battery cells 3 and the second photovoltaic battery cells 5. The first photovoltaic battery cells 3 and the second photovoltaic battery cells 5 each have the same structure and exhibit the same performance. More specifically, each first photovoltaic battery cell 3 is a thin film and includes a front surface 3a and a rear surface 3b. In the same manner, each second photovoltaic battery cell 5 is a thin film and includes a front surface 5a and a rear surface 5b. Conductors (not shown) are arranged on the rear surface 3b of the first photovoltaic battery cell 3 and the rear surface 5b of the second photovoltaic battery cell 5. The conductors may be arranged on the front surfaces 3a and 5a of the first and second photovoltaic battery cells 3 and 5.

As shown in FIG. 1, the first and second photovoltaic battery cells 3 and 5 are arranged in the front-to-rear direction and in the lateral direction of the solar panel so as to form a grid. Further, the first photovoltaic battery cells 3 are arranged adjacent to the second photovoltaic battery cells 5 in the lateral direction. The size and number of the first and second photovoltaic battery cells 3 and 5 may be changed in accordance with the size of the solar panel.

The tab wires 7a and 7b, each formed by a thin metal plate, are arranged at the right side or the left side of the solar panel at a fixed interval. The tab wires 7a and 7b electrically connect the first photovoltaic battery cells 3 and the second photovoltaic battery cells 5 of different lines in the front-to-rear direction. The form and number of the tab wires 7a and 7b may be changed. Further, the locations where the tab wires 7a and 7b are connected to the first and second photovoltaic battery cells 3 and 5 may be changed.

As shown in FIG. 3, in the solar panel, three interconnectors 9 are connected by the first connection portion 15a and the second connection portion 15b and form an interconnector group 90. The interconnector group 90, that is, the three interconnectors 9 and the first and second connection portions 15a and 15b, are punched out of a copper plate and formed integrally. Each interconnector group 90 is flat and horizontal to the first and second photovoltaic battery cells 3 and 5 (refer to FIG. 2). The interconnector group 90 may be formed by a metal plate other than a copper plate. Further, the number of the interconnectors 9 that form the interconnector group 90 may be changed as long as the number of the interconnectors 9 is two or more.

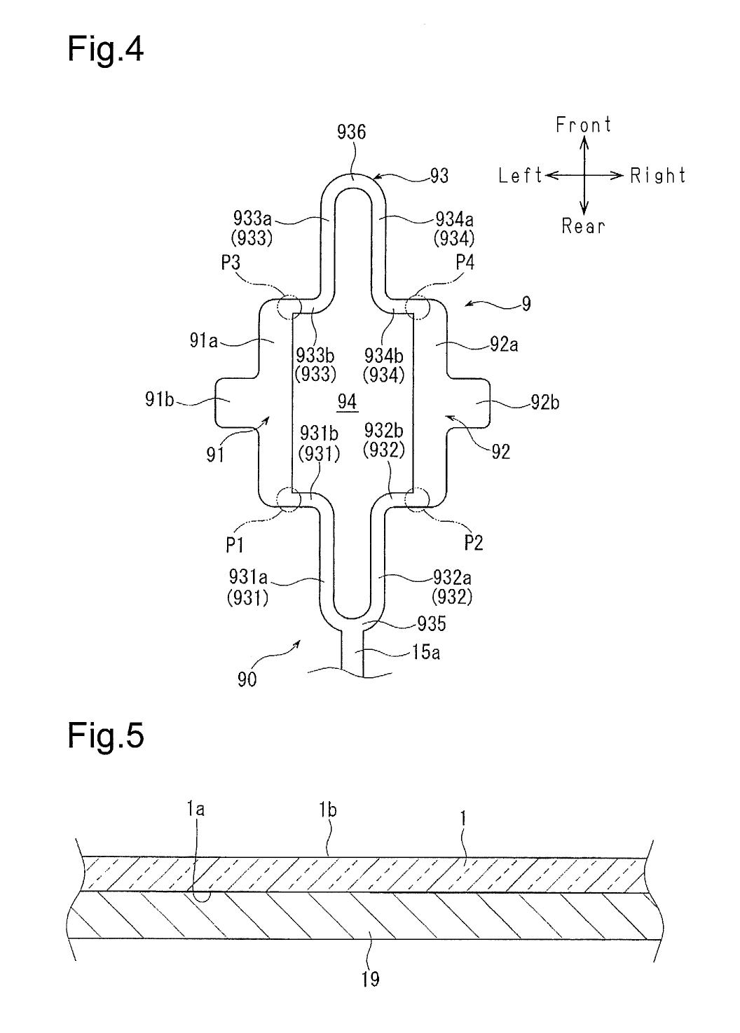

As shown in FIG. 4, each interconnector 9 includes a first electrode 91, a second electrode 92, and a connection body 93. The first electrode 91 is located at the left side of the interconnector 9, and the second electrode 92 is located at the right side of the interconnector 9. The first electrode 91 includes a first base 91a, which extends in the front-to-rear direction of the interconnector 9, and a first contact 91b, which is integrated with the first base 91a and extended from the first base 91a toward the left side. The second electrode 92 includes a second base 92a, which extends in the front-to-rear direction of the interconnector 9, and a second contact 92b, which is integrated with the second base 92a and extended from the second base 92a toward the right side.

The connection body 93 has the form of a fine line in a top view. The connection body 93 includes first to fourth detour portions 931 to 934 and first and second connection portions 935 and 936. The first detour portion 931 is a single line extending toward a rear side of the interconnector 9. The first detour portion 931 includes a first deformable portion 931a and a first bent portion 931b. The first deformable portion 931a extends toward the rear side of the interconnector 9. The first bent portion 931b is connected to a front end of the first deformable portion 931a and bent in the left direction at a substantially right angle toward the first electrode 91.

The second detour portion 932 is a single line extending toward the rear side of the interconnector 9. The second detour portion 932 is spaced apart from the right side of the first detour portion 931 by a predetermined interval. The second detour portion 932 includes a second deformable portion 932a and a second bent portion 932b. The second deformable portion 932a is parallel to the first deformable portion 931a and extended toward the rear side of the interconnector 9. The second bent portion 932b is connected to a front end of the second deformable portion 932a and bent in the right direction at a substantially right angle toward the second electrode 92.

The third detour portion 933 is separated from the first detour portion 931 toward the front side in the front-to-rear direction. The third detour portion 933 is a single line extending toward a front side of the interconnector 9. The third detour portion 933 includes a third deformable portion 933a and a third bent portion 933b. The third deformable portion 933a extends toward the front side of the interconnector 9. The third bent portion 933b is connected to a rear end of the third deformable portion 933a and bent in the left direction at a substantially right angle toward the first electrode 91.

The fourth detour portion 934 is separated from the second detour portion 932 toward the front side in the front-to-rear direction. The fourth detour portion 934 is a single line extending toward the front side of the interconnector 9. The fourth detour portion 934 is spaced apart from the right side of the third detour portion 933 by a predetermined interval. The fourth detour portion 934 includes a fourth deformable portion 934a and a fourth bent portion 934b. The fourth deformable portion 934a is parallel to the third deformable portion 933a and extended toward the front side of the interconnector 9. The fourth bent portion 934b is connected to a rear end of the fourth deformable portion 934a and bent in the right direction at a substantially right angle toward the second electrode 92. The first to fourth bent portions 931b to 934b each correspond to a bent portion.

The first connection portion 935 is located at a rear end of the connection body 93. The first connection portion 935 is a single line curved to have a semicircular shape and extend at the left and right sides so that the first connection portion 935 approaches a rear end of the first deformable portion 931a and a rear end of the second deformable portion 932a. The second connection portion 936 is located at a front end of the connection body 93. The second connection portion 936 is a single line curved to have a semicircular shape and extend at the left and right sides so that the second connection portion 936 approaches a front end of the third deformable portion 933a and a front end of the fourth deformable portion 934a.

The first connection portion 935 connects the rear end of the first deformable portion 931a to the rear end of the second deformable portion 932a. Thus, the first connection portion 935 connects the first detour portion 931 to the second detour portion 932. At a connection point P1, the first bent portion 931b is connected at a substantially right angle to a rear side of the first base 91a of the first electrode 91 from the right direction. This connects the first detour portion 931 to the first electrode 91. In the same manner, at a connection point P2, the second bent portion 932b is connected at a substantially right angle to a rear side of the second base 92a of the second electrode 92 from the left direction. This connects the second detour portion 932 to the second electrode 92.

The second connection portion 936 connects the front end of the third deformable portion 933a to the front end of the fourth deformable portion 934a. Thus, the second connection portion 936 connects the third detour portion 933 to the fourth detour portion 934. At a connection point P3, the third bent portion 933b is connected at a substantially right angle to a front side of the first base 91a of the first electrode 91 from the right direction. This connects the third detour portion 933 to the first electrode 91. In the same manner, at a connection point P4, the fourth bent portion 934b is connected at a substantially right angle to a front side of the second base 92a of the second electrode 92 from the left direction. This connects the fourth detour portion 934 to the second electrode 92. In such a manner, in the interconnector 9, the first electrode 91 and the second electrode 92 are connected to each other by the connection body 93 so that the first electrode 91 and the second electrode 92 are electrically connected to each other by the connection body 93, that is, the first to fourth detour portions 931 to 934 and the first and second connection portions 935 and 936.

Further, the connection body 93 connects the first electrode 91 to the second electrode 92 as described above to define a void 94 that extends in the front-to-rear direction and the lateral direction at the middle of the interconnector 9. The void 94 functions as a separator that separates the first detour portion 931, the first electrode 91, and the third detour portion 933 from the second detour portion 932, the second electrode 92, and the fourth detour portion 934 in the lateral direction.

As shown in FIG. 3, among the three interconnectors 9 that form the interconnector group 90, the first connection portion 15a connects the first one of the interconnectors 9 from the front and the second one of the interconnectors 9 from the front. More specifically, the first connection portion 15a is connected to the first connection portion 935 of the first interconnector 9 and the second connection portion 936 of the second interconnector 9. In the same manner, among the three interconnectors 9 that form the interconnector group 90, the second connection portion 15b connects the first connection portion 935 of the second one of the interconnectors 9 from the front and the second connection portion 936 of the third one of the interconnectors 9 from the front.

As shown in FIG. 3, in each interconnector 9, each first electrode 91 is connected to the corresponding first photovoltaic battery cell 3 so that the conductor of the first photovoltaic battery cell 3 is electrically connected to the first contact 91b. Each second electrode 92 is connected to the corresponding second photovoltaic battery cell 5 so that the conductor of the second photovoltaic battery cell 5 is electrically connected to the second contact 92b. Since the conductors are arranged on the rear surfaces 3b and 5b of the first and second photovoltaic battery cells 3 and 5 as described above, the first electrode 91 is connected to the rear surface 3b of the first photovoltaic battery cell 3 as shown in FIG. 2. In the same manner, the second electrode 92 is connected to the rear surface 5b of the second photovoltaic battery cell 5. To facilitate understanding, the form of the interconnector 9 is simplified in FIGS. 2 and 5 to 7. Further, the conductors may be arranged on the front surfaces 3a and 5a of the first and second photovoltaic battery cells 3 and 5 so that the first electrode 91 is connected to the front surface 3a of the first photovoltaic battery cell 3 and the second electrode 92 is connected to the front surface 5a of the second photovoltaic battery cell 5.

In this manner, as shown in FIG. 3, the interconnector group 90 is located between the first photovoltaic battery cell 3 and the second photovoltaic battery cell 5. Further, as shown in FIG. 2, the interconnector group 90 is arranged to be horizontal to the first photovoltaic battery cell 3 and the second photovoltaic battery cell 5. In the solar panel, the interconnector group 90, that is, the interconnectors 9, electrically connects the first photovoltaic battery cells 3 and the second photovoltaic battery cells 5 that are adjacent in the lateral direction. The interconnector group 90 spaces the first photovoltaic battery cells 3 apart from the second photovoltaic battery cells 5 by the interval W1.

Referring to FIG. 2, ethylene-vinyl acetate copolymer (EVA) is used for the encapsulant 11. The encapsulant 11 includes sheets of encapsulants 11a and 11b, which will be described below. The encapsulant 11 encapsulates and fixes and encapsulates each of the first and second photovoltaic battery cells 3 and 5, each of the tab wires 7a and 7b, and each of the interconnector groups 90 between the protection plate 1 and the back panel 13, more specifically, between the rear surface 1b of the protection plate 1 and a front surface 13a of the back panel 13. Thus, the encapsulant 11 is integrated with the protection plate 1 and the back panel 13 to fix the first and second photovoltaic battery cells 3 and 5 and the like in an encapsulated state and protect the first and second photovoltaic battery cells 3 and 5 from oxygen and moisture, which cause deterioration. Further, the encapsulant 11 includes a first silicone resin 17a and a second silicone resin 17b, which will be described below. For example, an ionomer resin, a silicone resin, or a polyolefin may be used for the encapsulant 11 instead of EVA.

The back panel 13 is formed by a metal plate of an aluminum alloy or the like. The back panel 13 is rectangular and includes the front surface 13a and a rear surface 13b. The front surface 13a opposes the rear surface 1b of the protection plate 1, each of the first and second photovoltaic battery cells 3 and 5, and the encapsulant 11. The rear surface 13b is opposite to the front surface 13a. The back panel 13, which is arranged on the rear surface of the encapsulant 11, cooperates with the encapsulant 11 to protect the first and second photovoltaic battery cells 3 and 5 and the like from moisture and oxygen, which cause deterioration. When the protection plate 1 has insufficient rigidity, the back panel 13 ensures the rigidity of the solar panel. The back panel 13 may be formed from a resin such as carbon-fiber-reinforced plastic (CFRP). Instead, the protection plate 1 and the back panel 13 may be formed from a resin so that the protection plate 1 and the back panel 13 ensure the rigidity of the solar panel. When the protection plate 1 is rigid enough to obtain the rigidity of the solar panel, a thin film of polyetherketone (PEK) may be used as the back cover instead of the back panel 13.

The first and second silicone resins 17a and 17b adhere each of the first and second photovoltaic battery cells 3 and 5 to the back panel 13. More specifically, the first silicone resin 17a adheres the front surface 13a of the back panel 13 to the rear surface 3b of each first photovoltaic battery cell 3, and the second silicone resin 17b adheres the front surface 13a of the back panel 13 to the rear surface 5b of each second photovoltaic battery cell 5. The first silicone resin 17a corresponds to a first adhesive, and the second silicone resin 17b corresponds to a second adhesive. The first silicone resin 17a and the second silicone resin 17b may be formed from the same material. Alternatively, the first silicone resin 17a and the second silicone resin 17b may be formed from different materials under different conditions.

The solar panel is manufactured as follows. First, as shown in FIG. 5, a vacuum molding jig 19 that can be heated is prepared. The protection plate 1 that has been formed in advance is mounted on the vacuum molding jig 19 so that the front surface 1a opposes the vacuum molding jig 19.

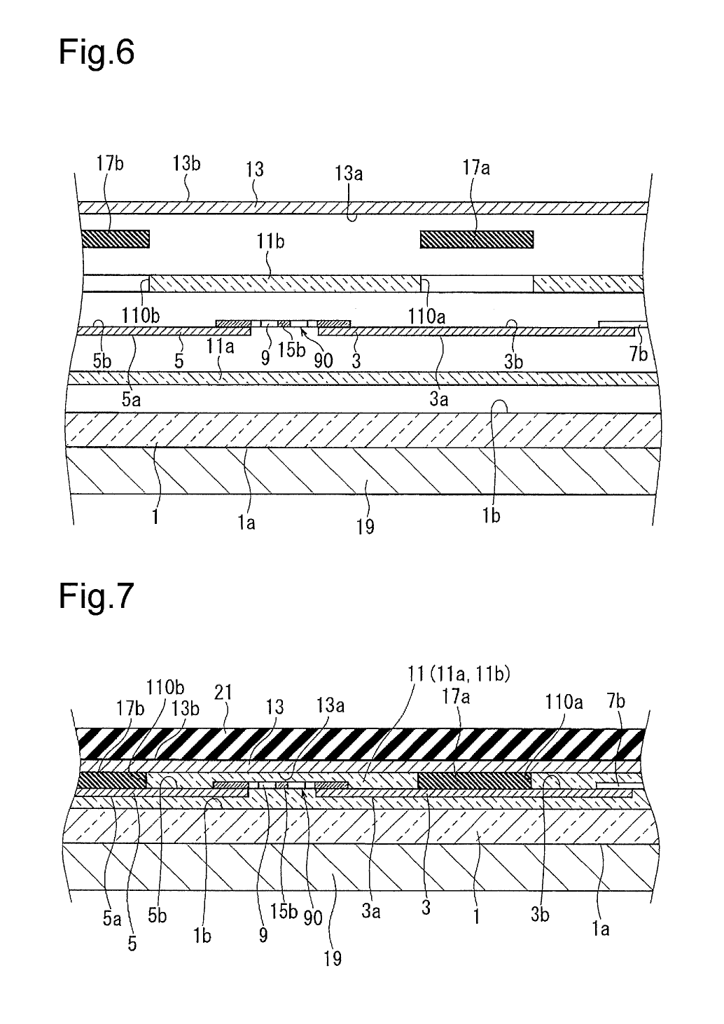

As shown in FIG. 6, in an encapsulating step, the encapsulant 11a, each of the first and second photovoltaic battery cells 3 and 5, the tab wires 7a and 7b, each interconnector group, and the encapsulant 11b are sequentially arranged on the rear surface 1b of the protection plate 1. The first and second photovoltaic battery cells 3 and 5 are electrically connected to one another by the tab wires 7a and 7b and the interconnector groups 90.

The encapsulant 11b includes a first cutout 110a and a second cutout 110b. The first cutout 110a opposes the rear surface 3b of each first photovoltaic battery cell 3, and the second cutout 110b opposes the rear surface 5b of each second photovoltaic battery cell 5. The number of the first cutouts 110a and the second cutouts 110b formed in the encapsulant 11b corresponds to the number of the first photovoltaic battery cells 3 and the second photovoltaic battery cells 5. Each of the first cutouts 110a is filled with the first silicone resin 17a, and each of the second cutouts 110b is filled with the second silicone resin 17b. Subsequently, the back panel 13 is arranged on the protection plate 1 so that the front surface 13a opposes the rear surface 1b of the protection plate 1.

After each of the photovoltaic battery cells 3 and 5 and the like are arranged and the first and second cutouts 110a and 110b are filled with the first and second silicone resins 17a and 17b, the lamination step is performed. More specifically, as shown in FIG. 7, a diaphragm 21 is pressed toward the vacuum molding jig 19 and a vacuum state is produced between the vacuum molding jig 19 and the diaphragm 21, that is, between the vacuum molding jig 19 and the above members that form the solar panel. Further, the vacuum molding jig 19 is heated when pressing the diaphragm 21 to soften the encapsulants lla and 11b and adhere the members to each other. Thus, each of the first photovoltaic battery cells 3 and 5, each of the tab wires 7a and 7b, and each interconnector group 90 are fixed in an encapsulated state between the rear surface 1b of the protection plate 1 and the front surface 13a of the back panel 13. Further, each first silicone resin 17a adheres each first photovoltaic battery cell 3 to the back panel 13, and each second silicone resin 17b adheres each second photovoltaic battery cell 5 to the back panel 13. This forms the solar panel.

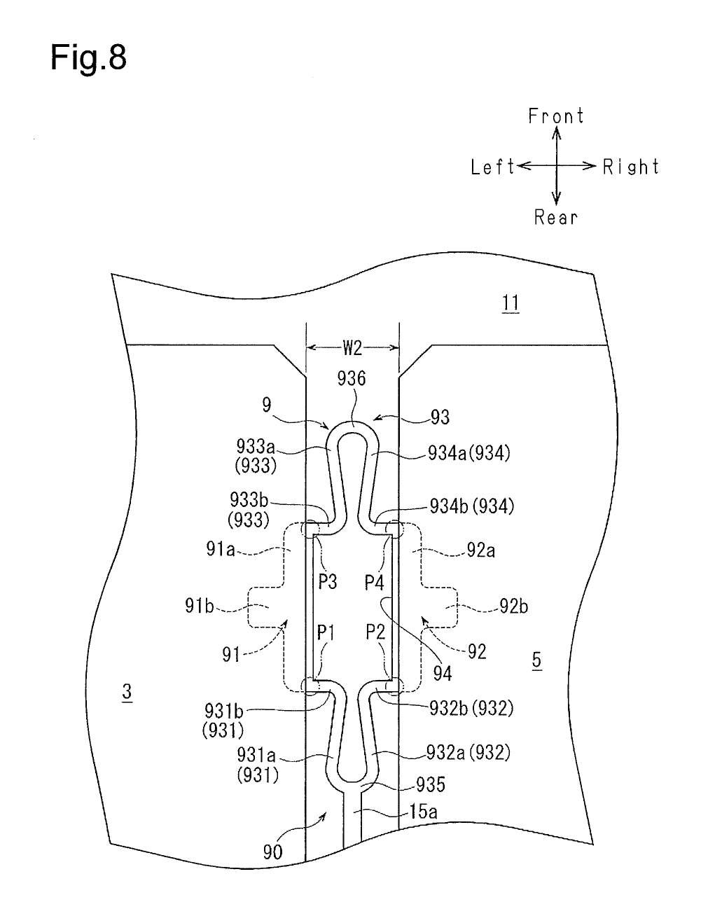

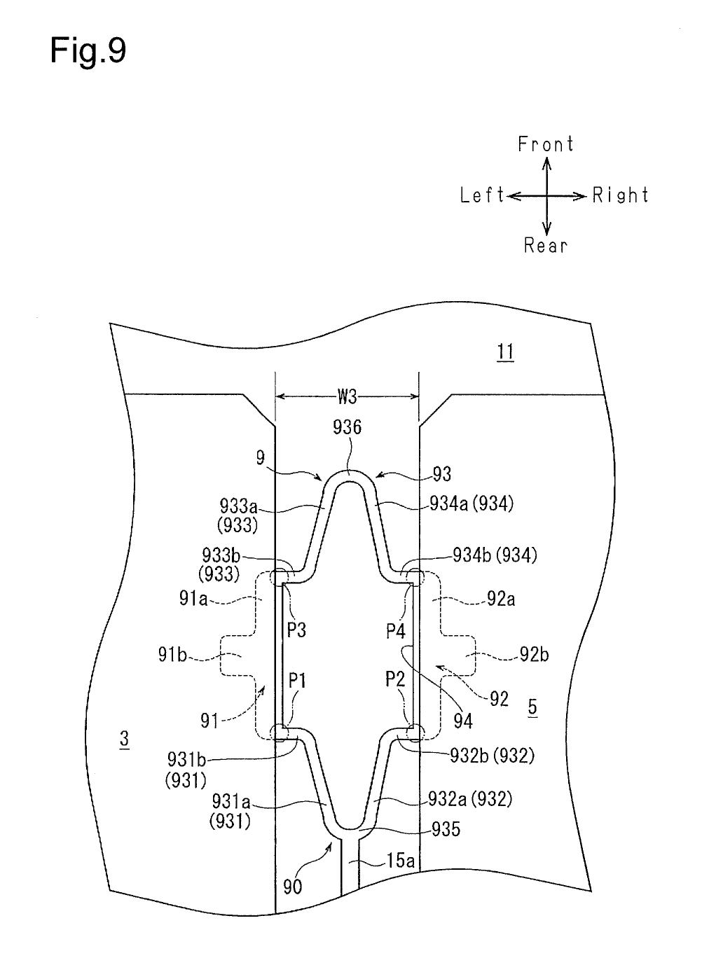

As shown in FIG. 3, in the solar panel, the interconnector group 90 electrically connects the first photovoltaic battery cell 3 and the second photovoltaic battery cell 5 that are adjacent to each other in the lateral direction. In each of the interconnectors 9 that form the interconnector group 90, the first electrode 91 and the second electrode 92 are connected by the connection body 93. Thus, when the solar panel undergoes thermal expansion and contraction resulting from temperature changes during manufacturing and use, the interval W1 of FIG. 3 between the first photovoltaic battery cell 3 and the second photovoltaic battery cell 5 changes to the interval W2 of FIG. 8 or the interval W3 of FIG. 9. The interval between the first electrode 91 and the second electrode 92 changes accordingly in each interconnector 9.

More specifically, as shown in FIG. 8, when the solar panel is contracted by temperature changes, the first photovoltaic battery cell 3 and the second photovoltaic battery cell 5 move toward each other in the lateral direction. In this case, the interval W2 between the first photovoltaic battery cell 3 and the second photovoltaic battery cell 5 is narrower than the interval W1 shown in FIG. 3. Accordingly, in the connection body 93 of each interconnector 9, as shown in FIG. 8, the first deformable portion 931a of the first detour portion 931 and the second deformable portion 932a of the second detour portion 932 are deformed to move toward each other in the lateral direction from the states shown in FIGS. 3 and 4. In the same manner, the third deformable portion 933a of the third detour portion 933 and the fourth deformable portion 934a of the fourth detour portion 934 are deformed to move toward each other in the lateral direction. Thus, the first electrode 91 and the second electrode 92 move toward each other in the lateral direction and narrow the middle void 94 of each interconnector 9 from the states shown in FIGS. 3 and 4.

As a result, in each interconnector 9, the first electrode 91 and the second electrode 92 are movable toward each other in the lateral direction while the deformation of the first to fourth deformable portions 931a to 934a absorbs the load of the pressing force applied in the lateral direction by each first photovoltaic battery cell 3 and each second photovoltaic battery cell 5 when the solar panel contracts. Thus, in the solar panel, even when the interval narrows between the first photovoltaic battery cell 3 and the second photovoltaic battery cell 5, breakage of the interconnector 9 in the thickness-wise direction does not occur that would be caused by the narrowed interval.

As shown in FIG. 9, when the solar panel is expanded by temperature changes, the first photovoltaic battery cell 3 and the second photovoltaic battery cell 5 move away from each other in the lateral direction. In this case, the interval W3 between the first photovoltaic battery cell 3 and the second photovoltaic battery cell 5 is wider than the interval W1 shown in FIG. 3. In the connection body 93 of each interconnector 9, as shown in FIG. 9, the first deformable portion 931a of the first detour portion 931 and the second deformable portion 932a of the second detour portion 932 are deformed to move away from each other in the lateral direction from the states shown in FIGS. 3 and 4. In the same manner, the third deformable portion 933a of the third detour portion 933 and the fourth deformable portion 934a of the fourth detour portion 934 are deformed to move away from each other in the lateral direction. Thus, the first electrode 91 and the second electrode 92 move away from each other in the lateral direction and widen the middle void 94 of each interconnector 9 from the states shown in FIGS. 3 and 4. As a result, in each interconnector 9, the first electrode 91 and the second electrode 92 are movable away from each other in the lateral direction while the deformation of the first to fourth deformable portions 931a to 934a absorbs the load of the pulling force in the lateral direction applied by each first photovoltaic battery cell 3 and each second photovoltaic battery cell 5 when the solar panel expands. Thus, in the solar panel, even when the interval is wide between each first photovoltaic battery cell 3 and each second photovoltaic battery cell 5, separation of the first electrode 91 from the first photovoltaic battery cell 3 and separation of the second electrode 92 from the second photovoltaic battery cell 5 do not occur that would be caused by the widened interval.

The first detour portion 931 and the third detour portion 933 are separated from each other in the front-to-rear direction, and the second detour portion 932 and the fourth detour portion 934 are separated from each other in the front-to-rear direction. Thus, in each interconnector 9, the first deformable portion 931a of the first detour portion 931 and the third deformable portion 933a of the third detour portion 933 are deformable independently from each other, and the second deformable portion 932a of the second detour portion 932 and the fourth deformable portion 934a of the fourth detour portion 934 are deformable independently from each other. Accordingly, the first to fourth deformable portions 931a to 934a are easily deformable. This allows the first electrode 91 and the second electrode 92 to easily move toward or away from each other in the lateral direction.

Thus, even when expanded and contracted by temperature changes, the solar panel of the first embodiment reduces electrical connection deficiencies of the first photovoltaic battery cells 3 and the second photovoltaic battery cells 5.

In particular, in each interconnector 9, the connection body 93 includes the single first detour portion 931, the single second detour portion 932, the single third detour portion 933, the single fourth detour portion 934, the single first connection portion 935, and the single second connection portion 936. The connection body 93 has the form of a fine line in a top view. This simplifies the structure of the connection body 93 in each interconnector 9 and thus facilitates manufacturing of each interconnector 9, that is, the interconnector group 90.

The connection body and the entire interconnector may be spiral and the entire interconnector may be meshed so that the interconnector is deformable in accordance with expansion and contraction of the solar panel caused by temperature changes. However, this complicates the shapes of the connection body and the entire interconnector and defines voids in the interconnector. It would thus be difficult for the encapsulant to enter the voids of the interconnector when the lamination step is performed. Accordingly, bubbles are easily formed between the encapsulant and the interconnector. This may reduce the force that connects the encapsulant to the interconnector. Further, since bubbles are exposed to the design surface of the solar panel, the aesthetic appeal of the solar panel would deteriorate.

In the solar panel of the first embodiment, the connection body 93 of the interconnector 9 has the form of a fine line as described above. This limits the formation of bubbles between the encapsulants 11a and 11b and each interconnector 9. Thus, the solar panel sufficiently connects the encapsulants 11a and 11b to each interconnector 9 without the aesthetic appeal being affected by bubbles exposed to the design surface.

In addition, in each interconnector 9, the first electrode 91 is connected to the first detour portion 931 by the first bent portion 931b, and the second electrode 92 is connected to the second detour portion 932 by the second bent portion 932b. In the same manner, the first electrode 91 is connected to the third detour portion 933 by the third bent portion 933b, and the second electrode 92 is connected to the fourth detour portion 934 by the fourth bent portion 934b. This limits deformation of the first to fourth bent portions 931b to 934b in each interconnector 9 even when the first to fourth deformable portions 931a to 934a are deformed as described above in the first to fourth detour portions 931 to 934. Thus, when the first electrode 91 and the second electrode 92 move toward or away from each other in the lateral direction as shown in FIGS. 8 and 9, deformation is limited at the connection point P1 of the first base 91a of the first electrode 91 and the first bent portion 931b, the connection point P2 of the second base 92a of the second electrode 92 and the second bent portion 932b, the connection point P3 of the first base 91a of the first electrode 91 and the third bent portion 933b, and the connection point P4 of the second base 92a of the second electrode 92 and the fourth bent portion 934b. Accordingly, in each interconnector 9, when the first electrode 91 and the second electrode 92 move toward or away from each other in the lateral direction, concentration of stress is limited at each of the connection portions P1 to P4. This increases the durability of each interconnector 9.

Further, in the solar panel, each first silicone resin 17a adheres each first photovoltaic battery cell 3 to the back panel 13, and each second silicone resin 17b adheres each second photovoltaic battery cell 5 to the back panel 13. This allows for easy positioning of each first photovoltaic battery cell 3 and each second photovoltaic battery cell 5 of the solar panel when manufactured. In addition, when the back panel is expanded and contracted by temperature changes during manufacturing and use, each first photovoltaic battery cell 3 and each second photovoltaic battery cell 5 are movable in accordance with the back panel 13. Thus, displacement of each first photovoltaic battery cell 3 and each second photovoltaic battery cell 5 from the protection plate 1 is limited in the solar panel. This restricts situations in which the main body 10a and the connection portions 10b of the shield 10 partially conceal the first photovoltaic battery cells 3 and the second photovoltaic battery cells 5 even when the solar panel is expanded and contracted by temperature changes.

Each first photovoltaic battery cell 3 and each second photovoltaic battery cell 5 are adhered to the back panel 13 at the rear surface 3b and the rear surface 5b, respectively. Thus, even when the solar panel is viewed from the front surface 1a of the protection plate 1, each of the first and second silicone resins 17a and 17b are hidden and cannot be seen. This improves the aesthetic appeal of the solar panel.

Further, in the solar panel, the three interconnectors 9 are connected to one another by the first and second connection portions 15a and 15b to form the interconnector group 90. Thus, in the interconnector group 90, the first and second connection portions 15a and 15b are used to set an equal interval between the interconnectors 9 in the front-to-rear direction. In the solar panel, this allows for easier positioning of the interconnectors 9 in the front-to-rear direction than when using three interconnectors 9 that are independent from one another to connect the first photovoltaic battery cells 3 and the second photovoltaic battery cells 5 that are adjacent in the lateral direction. In other words, in the solar panel, the interconnector group 90 eliminates the need to position the interconnectors 9 in the front-to-rear direction when connecting the first photovoltaic battery cells 3 and the second photovoltaic battery cells 5.

### Second Embodiment

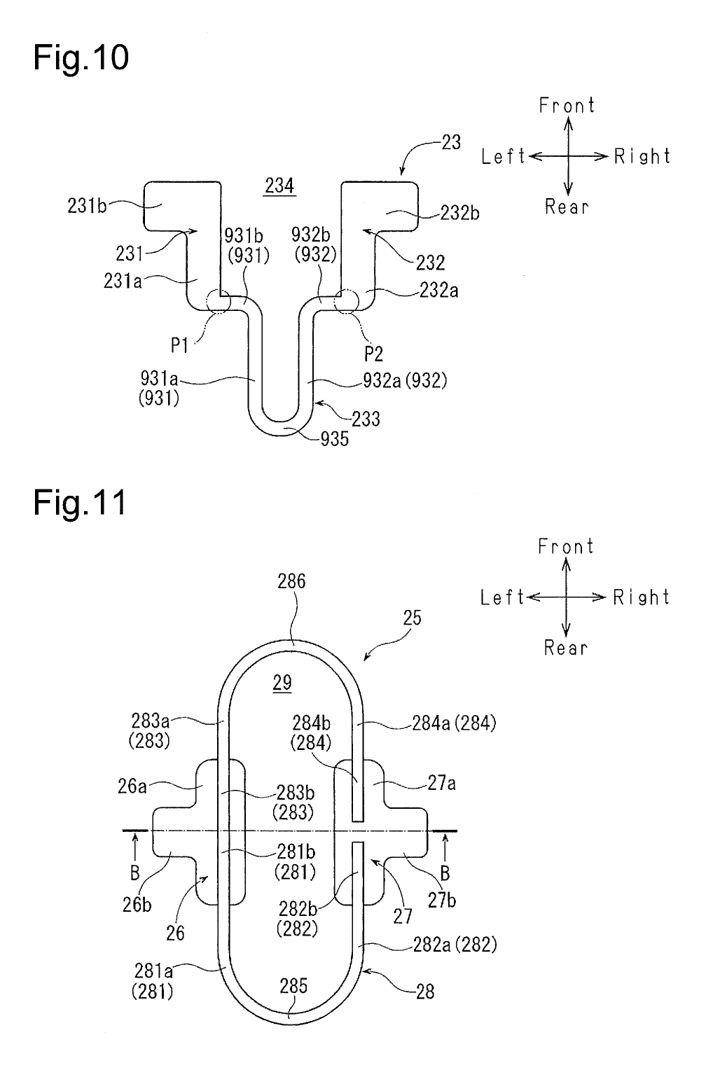

The solar panel of the second embodiment includes an interconnector 23 that is shown in FIG. 10 instead of the interconnector 9 of the solar panel of the first embodiment. The interconnector 23 is punched out of a copper plate. The number of the interconnectors 23 may be changed.

The interconnector 23 includes a first electrode 231, a second electrode 232, and a connection body 233. The first electrode 231 is located at the left side of the interconnector 23. The second electrode 232 is located at the right side of the interconnector 23. The first electrode 231 includes a first base 231a, which extends in the front-to-rear direction of the interconnector 23, and a first contact 231b, which is integrated with the first base 231a and extended from the first base 231a toward the left side. The second electrode 232 includes a second base 232a, which extends in the front-to-rear direction of the interconnector 23, and a second contact 232b, which is integrated with the second base 232a and extended from the second base 232a toward the right side.

The connection body 233 has the form of a fine line in a top view. The connection body 233 includes the first detour portion 931, the second detour portion 932, and the first connection portion 935 of the interconnector 9.

The first bent portion 931b of the first detour portion 931 is connected at a substantially right angle to a rear side of the first base 231a of the first electrode 231 from the right direction at the connection point P1. This connects the first detour portion 931 to the first electrode 231. In the same manner, the second bent portion 932b of the second detour portion 932 is connected at a substantially right angle to a rear side of the second base 232a of the second electrode 232 from the left direction at the connection point P2. This connects the second detour portion 932 to the second electrode 232. In the interconnector 23, the first electrode 231 and the second electrode 232 are connected to each other by the connection body 233 so that the first electrode 231 and the second electrode 232 are electrically connected by the first detour portion 931, the second detour portion 932, and the first connection portion 935.

Further, since the first electrode 231 and the second electrode 232 are connected by the connection body 233 as described above, a void 234 is defined in the middle of the interconnector 23. The void 234 functions as a separator that separates the first detour portion 931 and the first electrode 231 from the second detour portion 932 and the second electrode 232 in the lateral direction.

Although not illustrated in the drawings, in the same manner as the interconnector 9, the first electrode 231 of the interconnector 23 is connected to the first photovoltaic battery cell 3 so that the conductor of the first photovoltaic battery cell 3 is electrically connected to the first contact 231b. Further, the second electrode 232 is connected to the second photovoltaic battery cell 5 so that the conductor of the second photovoltaic battery cell 5 is electrically connected to the second contact 232b. Thus, in the solar panel, the interconnector 23 electrically connects the first photovoltaic battery cell 3 and the second photovoltaic battery cell 5 that are adjacent to each other in the lateral direction. The remaining structure of the solar panel of the second embodiment is the same as the solar panel of the first embodiment. Like or same reference numerals are given to those components that are the same as the corresponding components of the first embodiment and will not be described in detail.

In the solar panel, even when contraction or expansion of the solar panel caused by a change in temperature varies the interval between the first photovoltaic battery cell 3 and the second photovoltaic battery cell 5, the connection body 233 of the interconnector 23 deforms and moves the first electrode 231 and the second electrode 232 toward or away from each other in the lateral direction. As a result, in the interconnector 23 of the solar panel, the first electrode 231 and the second electrode 232 are movable toward or away from each other while the deformation of the first and second deformable portions 931a and 932a absorbs the load of the pressing force or the pulling force applied in the lateral direction by each first photovoltaic battery cell 3 or each second photovoltaic battery cell 5 when the solar panel contracts or expands.

In particular, in the interconnector 23, the connection body 233 includes the single first detour portion 931, the single second detour portion 932, and the single first connection portion 935. Thus, the structure of the connection body 233 of the interconnector 23 is simpler than the structure of the connection body 93 of the interconnector 9. This further facilitates manufacturing of the interconnector 23. The solar panel of the second embodiment also has the same advantages as the solar panel of the first embodiment.

### Third Embodiment

The solar panel of the third embodiment includes an interconnector 25 shown in FIG. 11 instead of the interconnector 9 of the solar panel of the first embodiment. The interconnector 25 includes a first electrode 26, a second electrode 27, and a connection body 28. The first electrode 26 and the second electrode 27 are punched out of a copper plate. The first electrode 26 is located at the left side of the interconnector 25, and the second electrode 27 is located at the right side of the interconnector 25. The first electrode 26 includes a first base 26a, which extends in the front-to-rear direction of the interconnector 25, and a first contact 26b, which is integrated with the first base 26a and extended from the first base 26a toward the left side. The second electrode 27 includes a second base 27a, which extends in the front-to-rear direction of the interconnector 25, and a second contact 27b, which is integrated with the second base 27a and extended from the second base 27a toward the right side.

The connection body 28 is formed by a single copper wire. The connection body 28 includes first to fourth detour portions 281 to 284 and first and second connection portions 285 and 286. The connection body 28 is annular in a top view. The first detour portion 281 includes a first deformable portion 281a, which extends toward a rear side of the interconnector 25, and a first fixed portion 281b, which is continuous with a front end of the first deformable portion 281a.

The second detour portion 282 is spaced apart from the right side of the first detour portion 281 by a predetermined interval. The second detour portion 282 includes a second deformable portion 282a, which extends toward the rear side of the interconnector 25, and a second fixed portion 282b, which is continuous with a front end of the second deformable portion 282a.

The third detour portion 283 includes a third deformable portion 283a, which extends toward a front side of the interconnector 25, and a third fixed portion 283b, which is continuous with a rear end of the third deformable portion 283a. The third fixed portion 283b is continuously integrated with the first fixed portion 281b.

The fourth detour portion 284 is spaced apart from the right side of the third detour portion 283 by a predetermined interval. The fourth detour portion 284 includes a fourth deformable portion 284a, which extends toward the front side of the interconnector 25, and a fourth fixed portion 284b, which is continuous with a rear end of the fourth deformable portion 284a. The fourth fixed portion 284b is non-continuous with the second fixed portion 282b. The fourth fixed portion 284b may be continuous with the second fixed portion 282b. Further, the first fixed portion 281b may be non-continuous with the third fixed portion 283b.

The first connection portion 285 is located at a rear end of the connection body 28. The first connection portion 285 is curved to have a semicircular manner shape and extend at the left and right sides so that the first connection portion 285 approaches a rear end of the first deformable portion 281a and a rear end of the second deformable portion 282a. The second connection portion 286 is located at a front end of the connection body 28. The second connection portion 286 is curved to have a semicircular shape and extend at the left and right sides so that the second connection portion 286 approaches a front end of the third deformable portion 283a and a front end of the fourth deformable portion 284a.

The rear end of the first deformable portion 281a and the rear end of the second deformable portion 282a are connected to each other by the first connection portion 285. Thus, the first detour portion 281 and the second detour portion 282 are connected to each other by the first connection portion 285. Further, the front end of the third deformable portion 283a and the front end of the fourth deformable portion 284a are connected to each other by the second connection portion 286. Thus, the third detour portion 283 and the fourth detour portion 284 are connected to each other by the second connection portion 286.

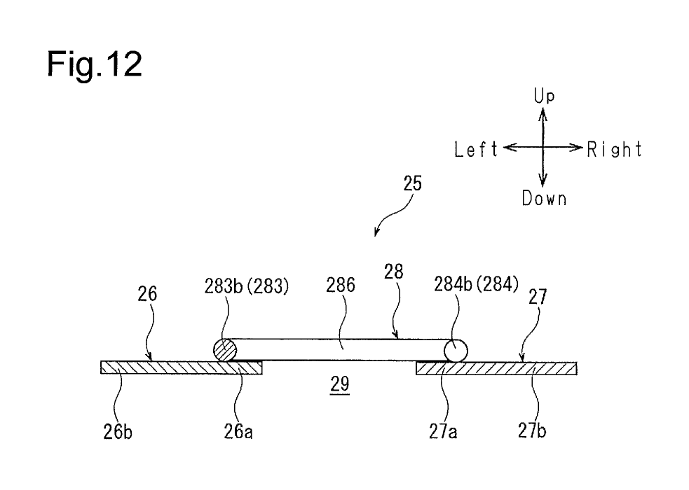

In addition, the first and third fixed portions 281b and 283b are soldered and electrically fixed to the first base 26a of the first electrode 26. In the same manner, the second and fourth fixed portions 282b and 284b are soldered and electrically fixed to the second base 27a of the second electrode 27. Thus, in the interconnector 25, as shown in FIG. 12, the connection body 28 is located above the first and second electrodes 26 and 27, and the first electrode 26 and the second electrode 27 are connected by the connection body 28. Accordingly, the first electrode 26 and the second electrode 27 are electrically connected to each other by the first to fourth detour portions 281 to 284 and the first and second connection portions 285 and 286. The connection body 28 may be located below the first and second electrodes 26 and 27.

Further, in the interconnector 25, the connection body 28 is annular. Thus, the inner side of the connection body 28, that is, the middle of the interconnector 25, defines a void 29 extending in the front-to-rear direction and the lateral direction. The void 29 functions as a separator that separates the first detour portion 281, the first electrode 26, and the third detour portion 283 from the second detour portion 282, the second electrode 27, and the fourth detour portion 284 in the lateral direction.

Although not illustrated in the drawings, in the same manner as the interconnector 9, the first electrode 26 of the interconnector 25 is connected to the first photovoltaic battery cell 3. Further, the second electrode 27 is connected to the second photovoltaic battery cell 5. Thus, in the solar panel, the interconnector 25 electrically connects the first photovoltaic battery cell 3 and the second photovoltaic battery cell 5 that are adjacent to each other in the lateral direction. The remaining structure of the solar panel of the third embodiment is the same as the solar panel of the first embodiment.

In the solar panel, even when contraction or expansion of the solar panel caused by a change in temperature varies the interval between the first photovoltaic battery cell 3 and the second photovoltaic battery cell 5, the connection body 28 of the interconnector 25 deforms and moves the first photovoltaic battery cell 3 and the second photovoltaic battery cell 5 toward or away from each other in the lateral direction. In the interconnector 25 of the solar panel, this allows the first electrode 26 and the second electrode 27 to move toward or away from each other in the lateral direction. Accordingly, the solar panel of the third embodiment also has the same advantages as the solar panel of the first embodiment.

Although the present invention has been described as above according to the first to third embodiments, the present invention is not limited to the first to third embodiments. It should be apparent to those skilled in the art that the present invention may be embodied in many other specific forms without departing from the spirit or scope of the invention. Particularly, it should be understood that the present invention may be embodied in the following forms.

For example, in the solar panel of the first embodiment, the three interconnectors 9 are connected to the first and second connection portions 15a and 15b to form the interconnector group 90. Instead, the three interconnectors 9 may be independent from one another. In the solar panel of the second embodiment, a plurality of the interconnectors 23 may be connected to one another to form the interconnector group. The same applies to the interconnectors 25 of the solar panel of the third embodiment.

In the interconnector 9 of the solar panel of the first embodiment, the first and second connection portions 935 and 936 may extend straight in the lateral direction. The same applies to the interconnector 23 and 25 of the solar panels of the second and third embodiments.

The interconnector 9 of the solar panel of the first embodiment does not have to include the first to fourth bent portions 931b to 934b. In such a case, the first and third deformable portions 931a and 933a may be directly connected to the first base 91a, and the second and fourth deformable portions 932a and 934a may be directly connected to the second base 92a. The same applies to the interconnector 23 of the solar panel of the second embodiment.

In the interconnector 9 of the solar panel of the first embodiment, for example, the first bent portion 931b may be included in only the first detour portion 931. The same applies to the interconnector 23 of the solar panel of the second embodiment.

The connection body 28 of the interconnector 25 of the solar panel of the third embodiment may include the first detour portion 281, the second detour portion 282, and the first connection portion 285 so that the connection body 28 is U-shaped in a top view.

Each first silicone resin 17a may adhere the front surface 3a of each first photovoltaic battery cell 3 to the rear surface 1b of the protection plate 1, and each second silicone resin 17b may adhere the front surface 5a of each second photovoltaic battery cell 5 to the rear surface 1b of the protection plate 1. In this case, it is preferred that each of the first and silicone resins 17a and 17b be translucent to limit decreases in the power generation efficiency.

The solar panels of the first to third embodiments do not have to be flat. Instead, the solar panels of the first to third embodiments may be curved.

The present invention is applicable to a solar panel mounted on a vehicle roof or a solar panel used for any of a variety of photovoltaic systems.

Therefore, the present examples and embodiments are to be considered as illustrative and not restrictive and the invention is not to be limited to the details given herein, but may be modified within the scope and equivalence of the appended claims.

1. An interconnector that is configured to electrically connect a first photovoltaic battery cell and a second photovoltaic battery cell to each other, wherein the first photovoltaic battery cell and the second photovoltaic battery cell are adjacent to each other in a first direction, the interconnector comprising:
a first electrode configured to be connected to the first photovoltaic battery cell;
a second electrode configured to be connected to the second photovoltaic battery cell; and
a connection body that connects the first electrode and the second electrode;
wherein a second direction is defined orthogonal to the first direction, and a first side and a second side are defined in the second direction; and
the connection body includes
a single first detour portion that is electrically connected to the first electrode and extended toward the first side in the second direction,
a single second detour portion that is electrically connected to the second electrode and extended toward the first side in the second direction, and
a single first connection portion that extends toward the first detour portion and the second detour portion in the first direction and connects the first detour portion and the second detour portion.

2. The interconnector according to claim 1, wherein at least one of the first detour portion and the second detour portion includes a bent portion extending in the first direction.

3. An interconnector that is configured to electrically connect a first photovoltaic battery cell and a second photovoltaic battery cell, wherein the first photovoltaic battery cell and the second photovoltaic battery cell are adjacent to each other in a first direction, the interconnector comprising:
a first electrode configured to be connected to the first photovoltaic battery cell;
a second electrode configured to be connected to the second photovoltaic battery cell; and
a connection body that connects the first electrode and the second electrode;
wherein a second direction is defined orthogonal to the first direction, and a first side and a second side are defined in the second direction; and
the connection body includes
a single first detour portion that is electrically connected to the first electrode and extended at the first side in the second direction,
a single second detour portion that is electrically connected to the second electrode and extended toward the first side in the second direction,
a single first connection portion that extends toward the first detour portion and the second detour portion in the first direction and connects the first detour portion and the second detour portion,
a single third detour portion that is electrically connected to the first electrode and extended toward the second side in the second direction,
a single fourth detour portion that is electrically connected to the second electrode and extended at the second side in the second direction, and
a single second connection portion that extends toward the third detour portion and the fourth detour portion in the first direction and connects the third detour portion and the fourth detour portion.

4. The interconnector according to claim 3, wherein at least one of the first detour portion, the second detour portion, the third detour portion, and the fourth detour portion includes a bent portion extending in the first direction.

5. The interconnector according to claim 3, whereinthe first detour portion is separated from the third detour portion in the second direction, and
the second detour portion is separated from the fourth detour portion in the second direction.

6. The interconnector according to claim 1, wherein the first electrode, the second electrode, and the connection body are formed from a single plate.

7. A solar panel comprising:
an interconnector;
a protection cover that is translucent from a front surface to a rear surface;
a back cover;
a first photovoltaic battery cell;
a second photovoltaic battery cell that is adjacent to the first photovoltaic battery cell in a first direction; and
an encapsulant that encapsulates and fixes the first photovoltaic battery cell, the second photovoltaic battery cell, and the interconnector between the protection cover and the back cover;
wherein a second direction is defined orthogonal to the first direction, and a first side and a second side are defined in the second direction;
the interconnector includes
a first electrode connected to the first photovoltaic battery cell,
a second electrode connected to the second photovoltaic battery cell, and
a connection body that connects the first electrode and the second electrode;
the connection body includes
a single first detour portion that is electrically connected to the first electrode and extended toward the first side in the second direction,
a single second detour portion that is electrically connected to the second electrode and extended toward the first side in the second direction, and
a single first connection portion that extends toward the first detour portion and the second detour portion in the first direction and connects the first detour portion and the second detour portion.

8. The solar panel according to claim 7, wherein
the encapsulant includes a first cutout opposing the first photovoltaic battery cell and a second cutout opposing the second photovoltaic battery cell,
the first cutout receives a first adhesive that adheres the protection cover or the back cover to the first photovoltaic battery cell and positions the first photovoltaic battery cell, and
the second cutout receives a second adhesive that adheres the protection cover or the back cover to the second photovoltaic battery cell and positions the second photovoltaic battery cell.
